(19) United States
(12) Patent Application Publication
(10) Pub. No.: US 2026/0291458 A1
(43) Pub. Date: Sep. 24, 2026

(54) SYSTEM AND METHOD FOR AUTOMATIC ADJUSTMENT OF REFERENCE GAIN

(71) Applicant: Shure Acquisition Holdings, Inc., Niles, IL (US)

(72) Inventors: Dusan Veselinovic, Chicago, IL (US); Michael Ryan Lester, Colorado Springs, CO (US)

(21) Appl. No.: 19/416,664

(22) Filed: Dec. 11, 2025

Related U.S. Application Data
(63) Continuation of application No. 18/062,876, filed on Dec. 7, 2022, now Pat. No. 12,519,438.
Application No. 18/062,876 is a continuation of application No. 17/169,262, filed on Feb. 5, 2021, now Pat. No. 11,552,611.
(60) Provisional application No. 62/971,850, filed on Feb. 7, 2020.

(51) Int. Cl. H03G 3/24; H04M 9/08; H04R 3/00; H04R 5/04; H04S 7/00

(52) U.S. Cl. CPC H03G 3/24; H04M 9/08; H04R 3/005; H04R 5/04; H04S 7/301; H04S 2400/13

(57) ABSTRACT

Systems and methods are provided for automatically adjusting a reference gain of an audio mixer having a reference channel for receiving a far end audio signal from a remote location as a reference signal and a plurality of audio input channels for receiving audio signals captured by a plurality of microphone element. An exemplary method includes determining an echo level in an input audio signal received at a given audio input channel, and automatically determining a gain amount for the reference channel based on the echo level. An exemplary system includes a reference gain adjuster configured to automatically determine a gain amount for the reference channel based on an echo level detected in an input audio signal received at a given audio input channel.

### CROSS-REFERENCE

This application is a continuation of U.S. patent application Ser. No. 18/062,876, filed on Dec. 7, 2022, which is a continuation of U.S. patent application Ser. No. 17/169,262, now U.S. Pat. No. 11,552,611, filed on Feb. 5, 2021, which claims the benefit of U.S. Provisional Patent Application No. 62/971,850, filed on Feb. 7, 2020. The contents of each application are incorporated by reference herein in their entirety.

### TECHNICAL FIELD

This disclosure generally relates to gain adjustment of a reference signal provided to a mixer for mixing audio signals from a plurality of acoustic sources, such as microphones used in a conferencing system. In particular, the disclosure relates to systems and methods for automatically adjusting the reference gain.

### BACKGROUND

Conferencing environments, such as boardrooms, conferencing settings, and the like, can involve the use of microphones for capturing sound from audio sources (also known as the “near end”) and loudspeakers for presenting audio from a remote location (also known as the “far end”). For example, persons in a conference room may be conducting a conference call with persons at a remote location. Typically, speech and sound from the conference room may be captured by microphones and transmitted to the remote location, while speech and sound from the remote location may be received and played on loudspeakers in the conference room. Multiple microphones may be used in order to optimally capture the speech and sound in the conference room.

In some cases, the microphones may pick up the speech and sound from the remote location that is played on the loudspeakers. In such situations, the audio transmitted to the remote location may include not only the speech and sound from the conference room, but also the speech and sound from the remote location, thus creating an undesirable echo for the persons at the remote location hearing their own speech and sound. If there is no correction, the audio transmitted to the remote location may therefore be low quality or unacceptable due to this echo.

Some existing communication systems utilize echo cancellation techniques to minimize, or cancel out, the echo in the mixed audio signal. For example, some systems utilize an acoustic echo canceller for each of the multiple microphones, and a mixer to subsequently mix and process each echo-cancelled microphone signal. However, these types of systems may be computationally intensive and complex. For example, separate and dedicated processing may be needed to perform acoustic echo cancellation on each microphone signal. Other systems place an acoustic echo canceller after the mixer. However, some such systems work poorly due to the need to constantly re-adapt to the mixed signal generated by the mixer, specifically where the mixer is dynamic and therefore, the gains on one or more of the mixer channels changes over time.

Accordingly, there is an opportunity for improved techniques that address these concerns.

### SUMMARY

The invention is intended to solve the above-noted problems by providing systems and methods designed to automatically adjust a gain of a reference input channel that is fed into a mixer for generating a mixed audio signal based on near end audio signals, wherein the reference input channel provides a far end audio signal to the mixer for gate-inhibit purposes.

One example embodiment provides a system, comprising a plurality of microphone elements, each microphone element configured to detect sound and convert the sound to a near end audio signal; at least one audio output device configured to output a far end audio signal comprising sound captured at a remote location; an audio mixer having a plurality of audio input channels for receiving audio signals captured by the plurality of microphone elements and a reference channel for receiving the far end audio signal as a reference signal; and a reference gain adjuster configured to automatically determine a gain amount for the reference channel based on an echo level detected in an input audio signal received at a given audio input channel.

Another example embodiment provides a method of automatically adjusting a reference gain of an audio mixer having a reference channel for receiving a far end audio signal from a remote location as a reference signal and a plurality of audio input channels for receiving audio signals captured by a plurality of microphone elements, the method comprising determining an echo level in an input audio signal received at a given audio input channel; and automatically determining a gain amount for the reference channel based on the echo level.

These and other embodiments, and various permutations and aspects, will become apparent and be more fully understood from the following detailed description and accompanying drawings, which set forth illustrative embodiments that are indicative of the various ways in which the principles of the invention may be employed.

### BRIEF DESCRIPTION OF THE DRAWINGS

FIG. 1 is a schematic diagram of a communication system including an automatic reference gain adjustment module, in accordance with some embodiments.

FIG. 2 is a flowchart illustrating operations for performing automatic reference gain adjustment using the communication system of FIG. 1, in accordance with some embodiments.

FIG. 3 is a flowchart illustrating operations for performing automatic reference gain adjustment when one or more microphone inputs are boosted, using the communication system of FIG. 1, in accordance with some embodiments.

### DETAILED DESCRIPTION

The description that follows describes, illustrates, and exemplifies one or more particular embodiments of the invention in accordance with its principles. This description is not provided to limit the invention to the embodiments described herein, but rather to explain and teach the principles of the invention in such a way to enable one of ordinary skill in the art to understand these principles and, with that understanding, be able to apply them to practice not only the embodiments described herein, but also other embodiments that may come to mind in accordance with these principles. The scope of the invention is intended to cover all such embodiments that may fall within the scope of the appended claims, either literally or under the doctrine of equivalents.

It should be noted that in the description and drawings, like or substantially similar elements may be labeled with the same reference numerals. However, sometimes these elements may be labeled with differing numbers, such as, for example, in cases where such labeling facilitates a more clear description. Additionally, the drawings set forth herein are not necessarily drawn to scale and in some instances, proportions may have been exaggerated to more clearly depict certain features. Such labeling and drawing practices do not necessarily implicate an underlying substantive purpose. As stated above, the specification is intended to be taken as a whole and interpreted in accordance with the principles of the invention as taught herein and understood to one of ordinary skill in the art.

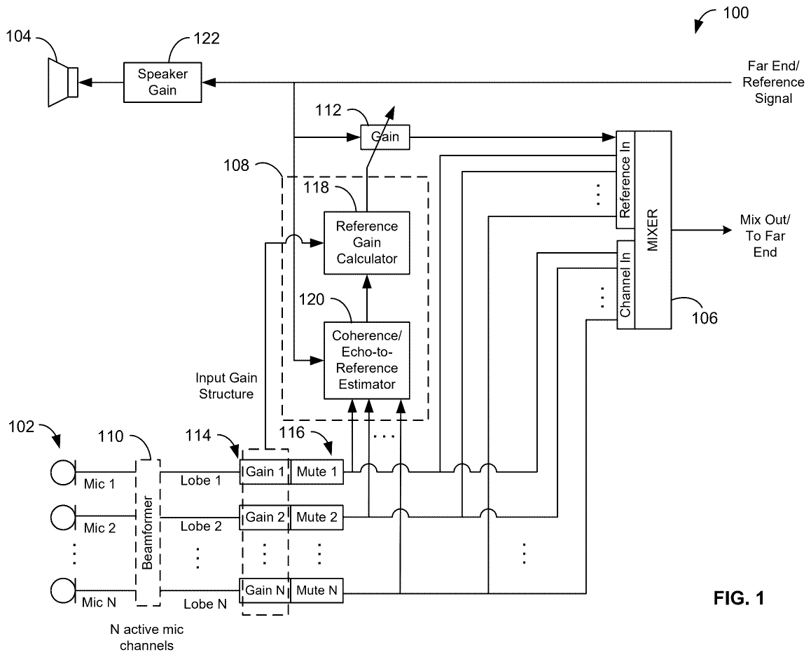

FIG. 1 is a schematic diagram of a communication system 100 comprising a plurality of microphones 102 for capturing sound from one or more audio sources in an environment (also referred to herein as “near end audio”), a loudspeaker 104 for presenting audio received from a remote location (also referred to herein as “far end audio”), and an audio mixer 106 for generating a mix of the near end audio for sending to the remote location. For example, environments such as conference rooms may utilize the communication system 100 to facilitate communication with persons situated at the remote location, which may be another room, building, city, or any other area that is separate from the given environment. The components of the communication system 100 may be in communication with each other using wired and/or wireless connections. In the latter case, the communication system 100 may further include a communications module for enabling wireless communication between various components of the communication system 100 itself, and/or to facilitate wireless communication with the remote location.

The types of microphones 102 and their placement in a particular environment may depend on the locations of the audio sources, physical space requirements, aesthetics, room layout, and/or other considerations. For example, in some environments, the microphones 102 may be placed on a table or lectern near the audio sources. In other environments, the microphones 102 may be mounted overhead to capture the sound from the entire room, for example. The communication system 100 may work in conjunction with any type and any number of microphones 102.

Various components included in the communication system 100 may be implemented using software executable by one or more servers or computers, such as a computing device with a processor and memory, by hardware (e.g., discrete logic circuits, application specific integrated circuits (ASIC), programmable gate arrays (PGA), field programmable gate arrays (FPGA), etc.), or using a combination software and hardware.

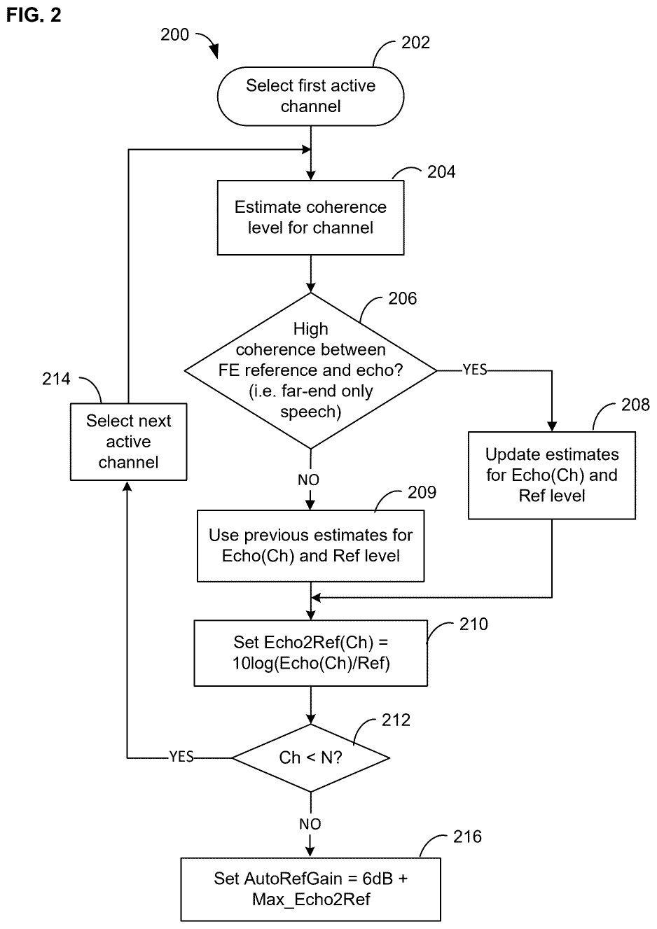

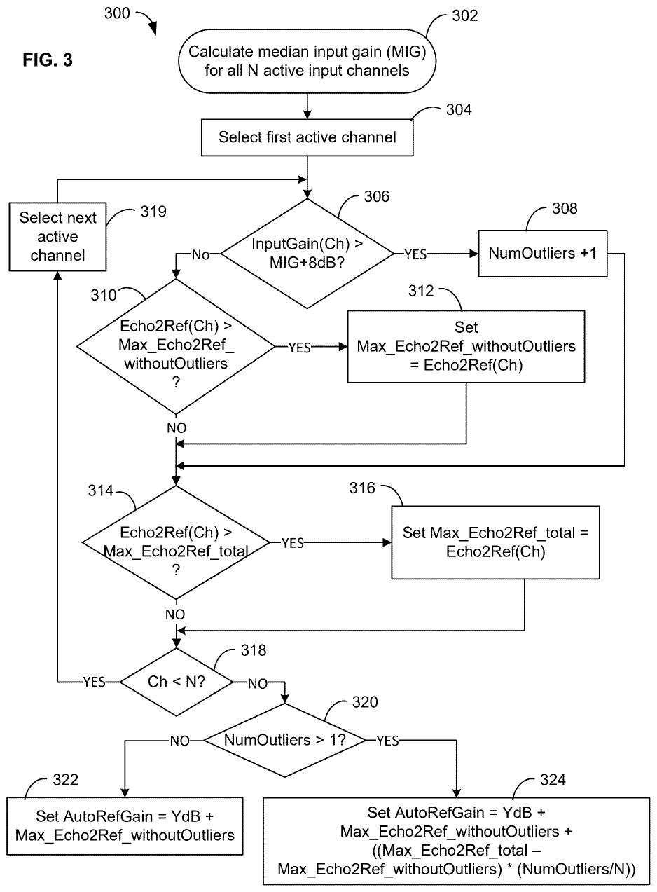

FIGS. 2 and 3 illustrate exemplary processes for utilizing the communication system 100, in accordance with embodiments. In particular, FIG. 2 illustrates a process 200 for automatically adjusting a gain of a reference input signal representing far end audio, using the communication system 100, and FIG. 3 illustrates a method 300 for performing automatic reference gain adjustment when one or more of microphone inputs are boosted, or have an extra gain structure, using the communication system 100. One or more processors and/or other processing components within the communication system 100 may perform any, some, or all of the steps of each of the processes 200 and 300. One or more other types of components (e.g., memory, input and/or output devices, transmitters, receivers, buffers, drivers, discrete components, etc.) may also be utilized in conjunction with the processors and/or other processing components to perform any, some, or all of the steps of each of the processes 200 and 300. In general, a computer program product in accordance with the embodiments includes a computer-usable storage medium (e.g., standard random access memory (RAM), an optical disc, a universal serial bus (USB) drive, or the like) having computer-readable program code embodied therein, wherein the computer-readable program code is adapted to be executed by a processor (e.g., working in connection with an operating system) to implement the processes described herein. In this regard, the program code may be implemented in any desired language, and may be implemented as machine code, assembly code, byte code, interpretable source code or the like (e.g., via C, C++, Java, Actionscript, Objective-C, Javascript, CSS, XML, and/or others).

Referring now to FIG. 1, the communication system 100 can include the microphones 102, loudspeaker 104, audio mixer 106, and an automatic reference gain adjustment module 108. Each of the microphones 102 (also referred to herein as a “microphone element”) can be configured to detect sound in the environment and convert the sound to an audio signal. In embodiments, some or all of the audio signals (also referred to herein as “near end audio signals”) from the microphones 102 may be processed by a beamformer 110 to generate one or more beamformed audio signals (or lobes), as is known in the art. In such cases, the beamformed audio signals may be provided to the audio mixer 106 as input audio signals, as shown in FIG. 1. While the following description may refer to audio signals from microphones 102 for the sake of simplicity, it is contemplated that the techniques described herein may be utilized with any type of acoustic source or signal, including the beamformed audio signals (or lobes) generated by beamformer 110. The beamformer 110 may be any suitable beamformer, such as, e.g., a delay and sum beamformer, etc.

As shown in FIG. 1, the audio mixer 106 receives audio signals, or audio input signals, from the microphones 102 and/or the beamformer 110 at respective audio input channels and generates a mixed audio signal using the received audio signals. The mixed audio signal generated by the mixer 106 may conform to a desired audio mix such that the audio signals from certain microphones 102 are emphasized and the audio signals from other microphones 102 are deemphasized or suppressed, as described herein. Exemplary embodiments of audio mixers are disclosed in commonly-assigned patents, U.S. Pat. Nos. 4,658,425 and 5,297,210, each of which is incorporated by reference in its entirety. In some embodiments, the mixed audio signal may be provided to an acoustic echo canceller (not shown) that is either included in, or coupled to, the communication system 100.

The loudspeaker 104 (also referred to herein as “audio output device”) can be configured to output audio signals received from the remote location (e.g., via wired or wireless communication). The received audio signals (also referred to herein as “far end audio signals”) may include speech and/or sound captured by microphones located at the remote location. Sometimes, one or more of the microphones 102 may pick up the far end audio as it is being played on the loudspeaker 104, in addition to the near end audio that is present in the environment. In such cases, if left unmitigated, the mixed audio signal may produce an undesirable echo due to persons at the remote location hearing their own speech and sound. One technique for minimizing this echo is to utilize a “gate-inhibit” technique that prevents the mixer 106 from outputting a mixed audio signal that includes the far end audio being played by the loudspeaker. This technique is achieved, at least in part, by providing the far end audio signal to a reference input channel of the mixer and adjusting a gain of the reference input channel so that the far end signal level is high enough to “win” against any “far end echoes” picked up by the microphones 102 and provided to the audio input channels of the mixer 106.

Existing reference gain adjustment systems require manual configuration by an installer while physically testing the environment for echo issues. Specifically, the installer manually boosts a gain of the reference input channel, for example, using a physical slider or other manual input device, until the gate inhibit feature of the mixer is activated. However, if the installer sets the gain too high, this may result in drowning out or suppressing the near end audio, particularly in double-talk situations, sluggish gating, and other undesirable effects. Thus, the effectiveness of existing systems depends greatly on the skill level of the installer or operator.

The communication system 100 shown in FIG. 1 includes an automatic reference gain adjustment module 108 configured to automatically adjust a gain amount applied to the reference input channel of the mixer 106 for receiving the far end audio signal transmitted by the remote location, based on one or more inputs from the communication system 100. According to embodiments, this gain amount (also referred to herein as “reference gain”) can be controlled using a reference gain 112, or reference gain device, which may be implemented in hardware (e.g., an amplifier or the like), software, or a combination thereof. Thus, the communication system 100 can precisely control the far end reference gain so as to mitigate an echo in the mixed audio signal provided to the remote location.

As shown in FIG. 1, the mixer 106 may have a plurality of audio input channels (e.g., N channels) for receiving audio signals captured by a plurality of microphones 102 (e.g., N or more microphones), a corresponding plurality of reference input channels (e.g., N channels) for receiving the same audio signals (e.g., to help the mixer 106 avoid reverberation and other undesirable effects due to multiple microphones picking up the same audio source), and an additional reference input channel for receiving the audio signal received from the remote location (i.e. the far end reference input channel). Based on the N+1 reference input channels (or “reference channels”), the mixer 106 selects mixer-matrix gains for each of the N channel inputs (i.e. the near end audio signals), such that the channels considered “active” are gated-on (e.g., by applying a gain of 0 dB) and the remaining channels, i.e. those considered “inactive,” are gated-off (e.g., by applying a low gain or attenuation, such as −20 dB). The input gains 114 are applied to all channel inputs, and the mixed output, or mixed audio signal, is obtained based on the selected combination of channel inputs and gains at the mixer 106. As described further below, when a far-end reference signal with sufficient gain is applied to the appropriate reference input channel of the mixer 106, the mixer 106 can gate-off select channel inputs, as needed, to prevent or minimize the presence of an echo in the mixed audio signal output by the mixer 106.

In the illustrated embodiment, each microphone 102 is coupled to, or corresponds to, a respective one of the audio input channels of the mixer 106. In other embodiments, the number of microphones 102 (i.e. “M” microphones) may exceed the number of audio input channels (i.e. M>N) and/or each audio input channel may be configured to receive a respective one of the plurality of beamformed audio signals (e.g., N signals) output by the beamformer 110, each beamformed audio signal including audio signals captured by multiple microphones 102.

As shown, each audio input channel has individually controllable gain and mute settings. The gain settings can be controlled using an input gain 114, or input gain device, that is coupled to each input channel of the mixer 106 and can be implemented using hardware (e.g., an amplifier or the like), software, or a combination thereof. Likewise, the mute settings can be controlled using a mute device 116 that is coupled to each input channel and can be implemented using hardware (e.g., a mute button or the like), software, or a combination thereof. In various embodiments, the gain devices 114 and/or the mute devices 116 may be included in the mixer 106, embedded in or coupled to the respective microphones 102, included in a separate component of the communication system 100, or a combination thereof.

The mute settings provide a mute status (e.g., muted or unmuted) of the audio input channel, or the microphone 102 coupled thereto, and based thereon, determine whether the corresponding audio input channel is active or inactive. Specifically, if a given microphone 102 is unmuted, the corresponding input channel will be deemed “active.” If, on the other hand, a given audio input channel or microphone 102 is muted, the audio input channel will be deemed “inactive.” In embodiments, muted or inactive input channels do not contribute to calculation of a median gain or “outliers” and thus, may not participate in the algorithm decision making described herein, for example, with respect to FIG. 3.

The input gain settings can be used to emphasize or de-emphasize certain active microphone(s) (e.g., the chairperson of a meeting) or audio input channels, while keeping the rest of the active microphones or channels at the same gain level. Since input gain levels affect the overall gain structure of the audio input channels, the input gain settings may be referred to as an input gain structure of the microphones 102. As shown in FIG. 1, the input gain structure is provided as an input to the automatic reference gain adjustment module 108 for calculating echo-to-reference estimates and the final reference gain 112, as described in further detail herein.

In embodiments, the input gain settings enable one or more active channels to be gated-on, or emphasized, more easily by the mixer 106. For example, if the input gain 114 for a first channel is increased or set to a higher level than that of the other channels, and audio at substantially similar sound levels are simultaneously received across multiple channels, including the first channel, the mixer 106 will perceive the first channel as having a higher gain level than the other channels and accordingly, will select, or gate-on, the first channel. As will be appreciated, decreasing the input gain 114 of a given channel can have the opposite effect, thus de-emphasizing the channel having a lower input gain level.

In some embodiments, the input gain for each microphone 102, or audio input channel, is a static setting that is either controlled manually by the installer or operator, or automatically set using an algorithm. For example, in a conference room situation, the input gain settings may be configured to emphasize the microphone 102 located at the head of the room or table. In other embodiments, the input gain is a flexible setting that can be adjusted for each meeting or event. For example, a select input gain 114 may be configured so that the microphone 102 being used by a specific speaker or participant is emphasized (or given preference), irrespective of their location in the room or table seat. In another example, each input gain 114 may be set to an equal gain level for one event, and a different combination of gain levels for another event. As will be appreciated, in the case of flexible input gain settings, the reference gain settings are adjusted accordingly.

As described herein, the mixer 106 can be configured to use a “gate-inhibit” technique, or algorithm, to prevent the audio input channels from “gating on,” or being activated, when they pick up the audio being played by the loudspeaker 104 (i.e. an echo). This involves boosting a gain of the far end reference input channel so that, when the far end signal is playing on the loudspeaker 104, the far end reference channel is the only channel that is gating on, and the remaining audio input channels are “gate-inhibited,” or prevented from gating on.

Typically, gating decisions are made by comparing an energy level (e.g., decibel level) of a given audio input channel to a current maximum energy level, e.g., the highest energy level of all input channels for a preset duration of time (e.g., 400 milliseconds), to determine whether the corresponding microphone 102 is picking up audio from an audio source, as will be appreciated. If the energy level is sufficiently high enough (e.g., equal to 90% or more of the maximum level), the audio input channel becomes active and, for example, a lobe is pointed towards the audio source (e.g., talker). To prevent the microphones 102 from gating on in response to picking up the loudspeaker audio, the audio input channels are additionally compared to the far end reference channel during a gating decision. If the signal level of a given audio input channel does not exceed a signal level of the far end reference channel, i.e. due to the audio input channel picking up the loudspeaker audio instead of the audio sources in the environment, the far end reference channel will “win” the gating decision, and the audio input channel will not be activated. However, since the far end reference channel is not actually a physical output channel, no outputs are provided to the mixer 106 for generating the mixed audio signal. In this manner, the far end audio can be prevented from causing audio input channels connected to the mixer 106 from gating on and creating an echo in the mixed audio signal.

The automatic reference gain adjustment module 108 (also referred to herein as a “reference gain adjuster”) can improve the functionality of this gate inhibit technique by automatically selecting an appropriate gain amount for the reference gain device 112 coupled to the far end reference input channel (or far end reference channel) based on an echo signal detected at one or more audio input channels (or audio channels), so that the far end audio signal “wins” the gating decision each time the microphones 102 pick up the audio playing on the loudspeaker 104 (i.e. an echo). In this manner, the reference gain amount can be configured to remove the echo signal from, or reduce a contribution of the echo signal to, the input audio signals before the audio mixer 106 generates the mixed audio signal for sending to the remote location. To achieve this, the reference gain adjuster 108 utilizes a reference gain calculator 118 and a coherence estimator 120 (also referred to herein as an “echo-to-reference estimator”), which may be included in the adjustment module 108, as shown in FIG. 1. In various embodiments, the reference gain adjuster 108 may be included in the mixer 106, provided as a separate component of the communication system 100, or a combination thereof. In some embodiments, the coherence estimator 120 may be part of an acoustic echo canceller (AEC) coupled to or included in the system 100, or may be configured to receive coherence information from the AEC.

According to embodiments, the reference gain calculator 118 is configured to calculate or determine an appropriate value or level for the reference gain 112 based on an echo-to-reference ratio received from the coherence estimator 120 and, in at least some cases, the input gain structure received from the input gain devices 114 (e.g., as described with reference to FIG. 3). The coherence estimator 120 is configured to determine the echo-to-reference ratio based on an echo level detected in the audio signal received at a given audio input channel. More specifically, the coherence estimator 120 may be configured to compare the reference signal to the near end audio signal to detect the presence of an echo, or echo signal, and determine a level of coherence based on the echo signal and the reference signal, and if there is high coherence, determine the echo-to-reference ratio for the given audio input channel by estimating an energy level of the echo signal (or “echo level”) and an energy level of the reference signal (or “reference level”).

The reference gain adjuster 108 is further configured to determine which active audio input channel has the highest (or worst) echo-to-reference ratio and use that highest ratio to determine the gain amount applied by the reference gain 112 to the far end reference input channel. More specifically, the reference gain calculator 118 is configured to automatically adjust or set the reference gain amount to a preset value that is a predetermined number of decibels (dB) higher than the highest echo-to-reference ratio. For example, in at least one embodiment, the reference gain calculator 118 calculates the reference gain amount by adding 6 dB to the highest echo-to-reference ratio determined for the active audio input channels. In this manner, the calculated reference gain will be high enough to “defeat” any echo signals present in the audio input channels of the mixer 106, but not so high that it would prevent the audio input channels from gating on when there is speech at the near end (e.g., a double-talk situation).

Referring now to FIG. 2, the above-described technique for automatically adjusting reference gain may be implemented using exemplary method or process 200, in accordance with embodiments. For example, process 200 may be performed by one or more components of the communication system 100, including the reference gain adjuster 108. Accordingly, process 200 will be described below with reference to the communication system 100 of FIG. 1.

As shown, the process 200 may begin at block 202 by selecting a first one of the N active audio input channels. As described herein, each audio input channel may have a mute setting that determines whether the channel is identified as “active” or “inactive” (e.g., an unmuted or muted status of the mute device 116, respectively). In embodiments, the reference gain adjuster 108 is configured to calculate echo-to-reference ratios for all active audio input channels, or otherwise analyze only the active audio channels for echo signals. Accordingly, block 202 may also include determining whether a given audio channel is active or inactive based on a mute setting associated with that channel.

At block 204, the coherence estimator 120 estimates or calculates a coherence level for the given active audio input channel, or how much of the audio signal received at the input channel is due to the far end audio signal (i.e. corresponds to echo) versus the near end audio signal. For example, the coherence estimator 120 may determine the coherence level by comparing the reference signal to the input audio signal using cross-correlation techniques or other suitable coherence computation involving the signal envelope and/or Fourier Transform of each signal. The coherence level may be a cross-correlation coefficient or other suitable metric obtained using said techniques.

Once the coherence level is estimated for the first channel, the process 200 continues to block 206 where the coherence estimator 120 determines whether there is high coherence between the input audio signal and the reference signal. For example, high coherence may be found if the coherence level calculated at step 204 is greater than a preset threshold (e.g., 80%). In embodiments, a high level of coherence can indicate that only the far-end audio is present in the audio signal received at the given input channel, i.e. the input audio signal only or mostly contains a far end echo (or echo signal) and/or no near end audio is present in the environment (e.g., because the near end talkers are presumably silent). A low level of coherence can indicate that the input audio signal is most likely due to near-end talkers (i.e. no or very little far-end echo is present in the environment). A medium level of coherence can indicate the presence of “double-talk” in the input audio signal (i.e. both near end audio and far end audio are present in the environment).

If there is high coherence between the two signals at block 206 (i.e. the input audio signal primarily contains a far-end echo), the input audio signal is treated as the “echo signal,” and the process 200 continues to block 208, where the coherence estimator 120 calculates a new estimate for the echo level (“Echo (Ch)”) based on an energy level of the input audio signal (which is the sum of the far-end echo and near-end speech, if any) and a new estimate for the reference level (“Ref”) based on an energy level of the reference signal (i.e. the far end audio). If, on the other hand, high coherence is not found at block 206 (i.e. the coherence level is determined to be medium or low), the process 200 continues to block 209, where the coherence estimator 120 uses or retrieves previous estimates for the echo level and reference level. That is, at block 208, the Echo (Ch) and Ref levels are updated based on current estimates, while at block 209, the Echo (Ch) and Ref levels remain at previously calculated values, i.e. are not adjusted or re-calculated.

In embodiments, the process 200 may be an iterative process that improves over time as the estimates calculated at block 208, and therefore, the final auto reference gain amount, becomes more accurate. In such cases, when the process 200 is initialized or executed for the first time, a set of initial values may be assigned to each of the echo level and the reference level (e.g., −60 dB or other small positive value) and the determination at block 206 may necessarily be “no” (i.e. no high coherence). The initial values may be replaced with newly estimated values for the echo and reference levels after the coherence estimator 120 first identifies the existence of high coherence at block 206. The estimated values may be stored in a memory of the system 100 and continuously updated at block 208 each time high coherence is found at block 206. When high coherence is not found, the last set of estimates may be used at block 209 as the echo level and reference level for the current auto reference gain calculation. In this manner, the reference gain amount can remain high enough to offset future echo situations, even if a current situation does not contain an echo.

In embodiments, the echo level and reference level estimates may be calculated using respective exponentially weighted first order moving average equations, namely:

$$Echo ( Ch ) = A * Echo ( Ch ) + ( 1 - A ) * AVG\_ECHO \_ENERGY$$

$$Ref = A * Ref + ( 1 - A ) * AVG\_REF \_ENERGY$$

In the above equations, the parameter “A” is a smoothing factor, such as, for example, a discrete-time equivalent of a time constant (for a low-pass first order filter). This parameter, along with the first order moving average equations, may be used to smooth out the energy estimates over time and prevent sudden and/or random jumps in the estimates. In other embodiments, other suitable equations or energy estimators may be used to smooth out the energy estimates, such as, for example, a different smoothing method or a higher-order low pass filter.

From either block 208 or 209, the process 200 continues to block 210. At block 210, an echo-to-reference level, or ratio, for the given channel (“Echo2Ref(Ch)”) is calculated by converting a ratio of echo level to reference level (Echo(Ch)/Ref) to decibel (dB) units using the equation: 10*log(Echo(Ch)/Ref). As should be appreciated, the exact values used for “Echo(Ch)” and “Ref” at block 210 will vary depending on whether or not these values were updated at block 208.

At block 212, the coherence estimator 120 determines whether there are more channels to analyze. If there are (i.e. Ch<N), the next channel is selected at block 214 and blocks 204 through 210 are repeated for that channel. This continues until an echo-to-reference ratio has been calculated for each remaining active audio channel, or all N active channels have been analyzed (i.e. Ch=N).

Once all active channels have been analyzed, the process 200 further includes, either at block 216 or just prior to block 216, comparing the echo-to-reference ratios calculated for the N active channels using the coherence estimator 120 to determine which audio input channel has the highest echo-to-reference ratio (“Max_Echo2Ref”). In some embodiments, the coherence estimator 120 provides the echo-to-reference ratio estimated for each audio channel to the reference gain calculator 118, and the reference gain calculator 118 determines which of the received ratios is the highest. In other embodiments, the coherence estimator 120 determines which echo-to-reference ratio is the highest and provides only the highest ratio to the reference gain calculator 118.

At block 216, the reference gain calculator 118 calculates a reference gain amount using the highest echo-to-reference ratio. In particular, the reference gain calculator 118 sets or adjusts the reference gain to a preset value (e.g., 6 dB) above the highest echo-to-reference ratio (i.e. AutoRefGain=6 dB+Max_Echo2Ref). The reference gain calculator 118 then uses the final reference gain amount to adjust the gain 112 applied to the far end reference channel.

In process 200, it is assumed that all input gains 114 are set to the same value or level and therefore, it is sufficient to use the worst case scenario, i.e. the highest echo-to-reference ratio among all active audio channels, to determine the reference gain amount. However, in cases where there is an extra gain structure, or boost, for certain input channels (referred to herein as “outliers”), the appropriate reference gain for the far end reference input channel must be adjusted to “defeat” the outliers. In such cases, process 300 shown in FIG. 3 may be used to calculate the reference gain amount.

Referring now to FIG. 3, process 300 is configured for performing automatic reference gain adjustment when one or more of the microphone input gains (e.g., input gains 114 in FIG. 1) are boosted, or has a specific input gain setting that affects the echo-to-reference level estimate for that channel. The process 300 may be performed by one or more components of the communication system 100, such as the reference gain adjuster 108 shown in FIG. 1, in accordance with embodiments. The input gain “outliers” may exist because, for example, the installer manually boosted the input gain 114 of one or more audio input channels (e.g., to boost the microphone 102 located at the head of the room, etc.).

In various embodiments, the process 300 may begin after completing block 216 of the process 200 shown in FIG. 2. Namely, once the echo-to-reference ratios are calculated for all N active channels, and a maximum echo-to-reference ratio is determined and provided to the reference gain calculator 118, the process 300 may begin at block 302 with the reference gain calculator 118 receiving an input gain structure of the audio input channels from the input gains 114 shown in FIG. 1, and calculating a median input gain (“MIG”) for all N active input channels based on these input gain amounts.

At block 304, the reference gain calculator 118 selects a first active audio input channel. At block 306, the reference gain calculator 118 scans or analyzes the selected channel in order to determine whether the channel is an outlier, or a channel whose input gain 114 is set to a level that is higher than the sum of MIG and XdB (where X is typically 8). If the determination at block 306 is “yes,” a counter for the number of outliers (NumOutliers) is incremented by 1 at block 308, and the process 300 goes directly to block 314. If the determination at block 306 is “no,” the process 300 continues to block 310.

At block 310, the reference gain calculator 118 determines whether the echo-to-reference level for the given channel (“Echo2Ref(Ch)”) is greater than a maximum echo-to-reference level estimate over all channels but excluding outlier channels (denoted as “Max_Echo2Ref_withoutOutliers”). If the answer is “yes,” the process 300 continues to block 312, where the Max_Echo2Ref_withoutOutliers estimate is set equal to the echo-to-reference level for the given channel. From block 312, the process 300 continues to block 314. If the answer at block 310 is “no,” the process 300 goes directly to block 314.

At block 314, the reference gain calculator 118 determines whether the echo-to-reference level for the given channel (“Echo2Ref(Ch)”) is greater than a maximum echo-to-reference estimate over all channels, including outlier channels (denoted as “Max_Echo2Ref_total”). If the answer is “yes,” the process 300 continues to block 316, where the Max_Echo2Ref_total estimate is set equal to the echo-to-reference level for the given channel. From block 316, the process 300 continues to block 318. If the answer at block 314 is “no,” the process 300 goes directly to block 318. In embodiments, the initial values for Max_Echo2Ref_withoutOutliers and Max_Echo2Ref_total may be set to −∞dB.

At block 318, the reference gain calculator 118 determines whether there are any other active audio input channels (i.e. CH<N). If there are, process 300 continues to block 319, where the next active channel is selected and blocks 306 through 316 are repeated for that channel. This loop may continue until there are no more active channels remaining (i.e. CH=N or the determination at block 318 is “no”), at which point the process 300 continues to block 320.

At block 320, if there is only one input channel with a very high input gain (i.e. NumOutliers=1, or only one outlier channel), the process 300 continues to block 322, where the reference gain (“AutoRefGain”)) is automatically set to YdB higher than the Max_Echo2Ref_withoutOutliers estimate (where Y is typically 6), thus basically ignoring the outlier channel. This may be preferred in embodiments so as to not allow the outlier channel with the high input gain to set the reference gain to a value that is too high, as that would make it very difficult for near-end talkers to “break in,” or for the near end audio to be picked up by the mixer 106.

If there is more than one outlier channel at block 320 (i.e. NumOutliers>1), the process 300 continues to block 324, where the reference gain (“AutoRefGain”) is calculated using the following equation:

$$AutoRefGain = YdB + Max\_Echo2Ref \_withoutOutliers + ( ( Num O u t l i ers / N ) * ( Max\_Echo2Ref \_total - Max\_Echo2Ref \_withoutOutliers ) ) ,$$

where Y is typically 6. In other words, the reference gain is linearly increased based on the number of outliers when there is more than one outlier. This allows the channels with high input gains to at least somewhat raise the amount of reference gain that is automatically applied.

The process 300 may end once the reference gain amount calculated at blocks 322 or 324 is applied to the reference gain 112 of the reference input channel. In this manner, the echo signal can be removed from the near end audio signals before a mixed audio signal is generated by the audio mixer 106 based on the near end audio signals.

Referring back to FIG. 1, the communication system 100 may also include a speaker gain 122 for controlling a gain level of the loudspeaker 104. The speaker gain 122 may affect the overall gain structure of the input channels and the “Echo2Ref” ratios estimated in method 200, as well as the final value of the reference gain calculated by either of the methods 200 and 300. According to embodiments, the speaker gain 122, or speaker gain device, may be implemented in hardware (e.g., an amplifier or the like), software, or a combination thereof.

Thus, systems and methods are provided herein that can mitigate an echo in a mixed audio signal provided to a remote location, wherein the mixed audio signal is generated by a mixer using audio signals captured by microphones in an environment that further includes a loudspeaker for playing a far end audio signal received from the remote location. The microphones can be prevented from contributing far end audio to the mixed audio signal by automatically adjusting a gain applied to a far end reference input channel that is used by the mixer to determine whether the audio channels should be activated due to detection of near end audio.

While embodiments shown and described herein include multiple audio input channels, other embodiments may include a communication system with a single audio input channel. Also, though a particular audio communication system is shown and described herein, other embodiments may include any type of system with multiple, or single, input channels and a reference input channel for controlling gating decisions based on a contribution of the reference signal in the environment. For example, the techniques described herein may be used in other situations where setting the reference gain automatically to an appropriate level can help determine the activity/contribution of the reference signal in the near-end signal (mix), and can allow the mixer decisions to be used to temporarily inhibit, disable, enable, or otherwise control other types of actions or mechanisms, such as, for example, voice, noise, and/or disturbance activity detectors in the near end, which attempt to determine if near end sounds in the room represent talkers or noise but should not do so if the near-end source of sound is associated with an echo; automatic focus of existing lobes, which attempts to better focus a beam to the exact position of the near-end talker in the room, but should not do so if the near-end source of sound is associated with an echo; and/or automatic placement of various lobes, which attempts to initially place a beam or lobe towards the position of the near-end talker in the room, but should not do so if that near-end source of sound is associated with an echo. Examples of such other systems are disclosed in commonly-assigned patent application U.S. Ser. No. 16/887,790 and U.S. Ser. No. 16/826,115, each of which is incorporated by reference in its entirety.

Any process descriptions or blocks in the figures, such as, e.g., FIGS. 2 and 3, should be understood as representing modules, segments, or portions of code which include one or more executable instructions for implementing specific logical functions or steps in the process, and alternate implementations are included within the scope of the embodiments of the invention in which functions may be executed out of order from that shown or discussed, including substantially concurrently or in reverse order, depending on the functionality involved, as would be understood by those having ordinary skill in the art.

This disclosure is intended to explain how to fashion and use various embodiments in accordance with the technology rather than to limit the true, intended, and fair scope and spirit thereof. The foregoing description is not intended to be exhaustive or to be limited to the precise forms disclosed. Modifications or variations are possible in light of the above teachings. The embodiment(s) were chosen and described to provide the best illustration of the principle of the described technology and its practical application, and to enable one of ordinary skill in the art to utilize the technology in various embodiments and with various modifications as are suited to the particular use contemplated. All such modifications and variations are within the scope of the embodiments as determined by the appended claims, as may be amended during the pendency of this application for patent, and all equivalents thereof, when interpreted in accordance with the breadth to which they are fairly, legally and equitably entitled.

1-20. (canceled)

21. A system comprising:
a plurality of microphone elements, each microphone element configured to detect sound and convert the sound to a near end audio signal;
at least one audio output device configured to output a far end audio signal comprising sound captured at a remote location;
an audio mixer having a plurality of audio input channels for receiving audio signals captured by the plurality of microphone elements and a reference channel for receiving the far end audio signal as a reference signal, the audio mixer configured to generate a mixed audio signal based on the audio signals received at the plurality of audio input channels;
an acoustic echo canceller coupled to the audio mixer; and
a reference gain adjuster configured to automatically determine a reference gain amount for the reference channel based on an echo level detected in an input audio signal received at a given audio input channel, and apply the reference gain amount to the far end audio signal prior to receipt in the reference channel as the reference signal.

22. The system of claim 21, wherein the acoustic echo canceller is configured to receive the mixed audio signal from the audio mixer.

23. The system of claim 21, wherein the acoustic echo canceller is configured to determine coherence information based on the far end audio signal and a near end audio signal received at the given audio input channel, and the reference gain adjuster is configured to receive the coherence information from the acoustic echo canceller.

24. The system of claim 23, wherein the reference gain adjuster is configured to determine the reference gain amount based on the coherence information received from the acoustic echo canceller.

25. The system of claim 21, wherein the reference gain adjuster is configured to determine the echo level by:
determining a coherence level based on the far end audio signal and the input audio signal received at the given audio input channel; and
based on the coherence level being greater than a preset threshold, using a signal energy level of the input audio signal as the echo level.

26. The system of claim 25, wherein the reference gain adjuster is configured to, based on the coherence level not being greater than the preset threshold, use a previously stored echo level.

27. The system of claim 21, wherein the reference gain adjuster determines the reference gain amount based on an echo-to-reference ratio calculated using the echo level and a reference level determined based on the far end audio signal.

28. The system of claim 27, wherein the reference gain adjuster is further configured to:
calculate an echo-to-reference ratio for each of the plurality of audio input channels;
determine which audio input channel has a highest echo-to-reference ratio; and
calculate the reference gain amount using the highest echo-to-reference ratio.

29. The system of claim 28, wherein the reference gain adjuster further determines the reference gain amount by adding a preset value to the highest echo-to-reference ratio.

30. The system of claim 21, wherein each audio input channel has a mute setting that determines if the audio input channel is active or inactive, and the reference gain adjuster is configured to analyze active audio input channels for echo signals.

31. The system of claim 21, wherein the audio mixer is configured to make gating decisions for the plurality of audio input channels by comparing each audio input channel of the plurality of audio input channels to the reference channel.

32. The system of claim 31, wherein making the gating decisions comprises preventing a given audio input channel from gating on based on a signal energy level of the near end audio signal received at the given audio input channel being lower than a signal energy level of the reference signal received in the reference channel.

33. A method of automatically adjusting a reference gain of an audio mixer having a reference channel for receiving a far end audio signal from a remote location as a reference signal and a plurality of audio input channels for receiving audio signals captured by a plurality of microphone elements, the audio mixer configured to generate a mixed audio signal based on the audio signals, the method comprising:
determining an echo level in an input audio signal received at a given audio input channel;
automatically determining a reference gain amount for the reference channel based on the echo level;
applying the reference gain amount to the far end audio signal prior to receipt in the reference channel as the reference signal; and
providing the mixed audio signal to an acoustic echo canceller coupled to the audio mixer.

34. The method of claim 33, wherein determining the echo level comprises:
determining a coherence level based on the input audio signal and the far end audio signal; and
based on the coherence level being greater than a preset threshold, using a signal energy level of the input audio signal as the echo level.

35. The method of claim 34, further comprising:
based on the coherence level not being greater than the preset threshold, using a previously stored echo level.

36. The method of claim 33, wherein automatically determining the reference gain amount comprises:
calculating an echo-to-reference ratio using the echo level and a reference level determined based on the far end audio signal; and
determining the reference gain amount based on the echo-to-reference ratio.

37. The method of claim 36, wherein calculating the echo-to-reference ratio comprises:
calculating an echo-to-reference ratio for each of the plurality of audio input channels;
determining which audio input channel has a highest echo-to-reference ratio; and
using the highest echo-to-reference ratio for determining the reference gain amount.

38. The method of claim 37, wherein determining the reference gain amount further comprises adding a preset value to the highest echo-to-reference ratio.

39. The method of claim 33, further comprising:
receiving coherence information from the acoustic echo canceller, the coherence information based on the far end audio signal and a near end audio signal received at the given audio input channel; and
determining the reference gain amount based on the coherence information.

40. The method of claim 33, further comprising:
making gating decisions for the plurality of audio input channels by comparing each audio input channel of the plurality of audio input channels to the reference channel.
